(19) United States
(12) Patent Application Publication
(10) Pub. No.: US 2002/0013049 A1
(43) Pub. Date: Jan. 31, 2002

(54) Process for forming a conducting structure layer that can reduce metal etching residue

(76) Inventors: Teng-Tang Yang, Changhua Hsien (TW); Kun-Yi Lu, Tainan (TW); Ying-Chang Chia, Hsinchu (TW); Jiin-Shiarng Wen, Hsinchu (TW)

Correspondence Address: J C Patents Inc, 4 Venture, Suite 250, Irvine, CA, 92618, US

(21) Appl. No.: 09/849,460

(22) Filed: May 4, 2001

(30) Foreign Application Priority Data
Jul. 27, 2000 (TW) 89115000

(51) Int. Cl. H01L 21/44; H01L 21/4763; H01L 29/40; H01L 23/48; H01L 23/52

(52) U.S. Cl. 438/653; 438/652; 438/656; 438/660; 438/687; 438/688; 257/750; 257/751; 257/762; 257/763; 257/765

(57) ABSTRACT

A process for forming a conducting structure layer that can reduce metal etching residues, in which a pre in-situ metal layer is added before a metal layer is deposited. The pre in-situ metal layer enables the crystalloid of the metal layer to grow more 5 evenly, and thus reduces the etching residues of the conducting structure layer. A structure of a conducting structure layer is also provided.

### CROSS-REFERENCE TO RELATED APPLICATION

This application claims the priority benefit of Taiwan application Ser. No. 89115000, filed on Jul. 27, 2000.

### BACKGROUND OF THE INVENTION

1. Field of the Invention

The present invention relates to a process and a structure of semiconductor fabrication. More particularly, the present invention relates to a process and a structure for reducing metal etching residue. During the formation of a conducting structure layer, a pre in-situ metal layer is added before a metal layer deposits in order to reduce etching residue on the conducting structure layer.

2. Description of Related Art

Metals are commonly used as interconnecting material in integrated circuits, and they often form conducting structure layers with multi-layer structures. Often, dopants are added in metals in order to improve their properties. However, dopants cause uneven crystal growth when metals are deposited. As a result, etching residue appears, after an etching step on a conducting structure layer.

Take aluminum for example, in order to improve electron migration coefficient and to lower the spiking formed by mutual diffusion of aluminum and silicon substrate, dopants such as copper, silicon and so on, are added in aluminum. Thus an alloy of aluminum, silicon, and copper is used as the main material for the metal layer of a conducting structure layer.

In order to prevent the mutual diffusion of aluminum and silicon, and the decrease of resistance between the two, it is necessary to add a barrier layer with good insulating effect between the metal layer and the silicon substrate. The barrier layer is generally composed of a titanium layer and a titanium nitride layer. Normally, after the barrier layer deposits, either the wafer is exposed to the air for a period of time or a thermal treatment is conducted to increase the insulating ability of titanium nitride. When the thermal treatment is conducted, the titanium at the bottom of the layer and the surface of the silicon substrate form a layer of titanium silicide that decreases the resistance between the conducting structure layer and silicon substrate. Afterwards, a metal layer is deposited on the barrier layer and then, an anti-reflective layer is deposited on the metal layer. The anti-reflective layer comprises titanium nitride. The barrier layer, the metal layer, and the anti-reflective layer together form the conducting structure layer.

FIG. 1A is a cross section drawing of a conventional conducting structure layer. The conducting structure layer is formed on a semiconductor substrate 10. The process includes forming a dielectric layer 12 on the semiconductor substrate layer 10. In the dielectric layer 12 there is an opening 14 which exposes part of the component area on the substrate 10. A conformal barrier layer 20 is formed on the opening 14 and the dielectric layer 12. Afterwards, the barrier layer 20 is processed either by a thermal treatment or by being cooled in the air for a period of time. A metal layer 24 is formed on the barrier layer 20 and then an anti-reflective layer 26 is formed on the metal layer 24. Refer to FIG. 1B, the metal layer 24 and the barrier layer 20 form a conventional conductive structure layer after they are defined by photolithography etching. In the process of etching, some point-shaped residues 16 remain on the exposed dielectric layer 12. One of the possible causes for the conventional etching residues is connected with the processing of the dielectric layer 20. When the barrier layer 20 is processed, oxides are easily formed in the crystal interspaces on the surface of the barrier layer 20, which causes uneven metal crystal growth when the metal layer 24 is formed afterwards. The uneven metal crystal growth leads to uneven dopant distribution. As a result, some point-shaped residues 16 remain on the exposed dielectric layer 12 in the process of etching the inducting structure layer.

FIG. 2 is an electron microscope picture showing that, on the conventional conducting structure, there exist residues that can not be completely removed after the etching is conducted.

### SUMMARY OF THE INVENTION

In view of this, the present invention provides a process and its structure that is capable of reducing metal etching residues in forming a conducting structure layer. It is possible to add a pre in-situ metal layer in the inducting structure layer to make the crystal growth of the metal layer more even so as to reduce the probability of the occurrence of the etching residues after the etching of the conducting structure layer.

The present invention provides a process for forming a conducting structure layer that can reduce metal etching residues. Before a metal layer is deposited on a substrate, a pre in-situ metal layer is first deposited. Then the metal layer is deposited under a continuous vacuum condition.

In the above-described process, the function of the added pre in-situ metal layer is to provide the metal layer with an appropriate depositing surface to make the crystal growth of the metal layer more even, so that occurrence of the uneven dopant distribution phenomenon is reduced. As a result, the occurrence probability of the etching residues after the etching of the conducting structure layer is reduced. The pre in-situ metal layer and the metal layer form the entire or part of the conducting structure layer.

The present invention provides a structure for forming a conducting structure layer that can reduce metal etching residues. The conducting structure is formed on a substrate. There is a pre in-situ metal layer on the substrate, and on the pre in-situ layer, there is a metal layer. This structure can reduce the probability of occurrence of the etching residues after the metal layer passes the etching step. The pre in-situ metal layer and the metal layer form the entire or part of the conducting structure layer.

It is to be understood that both the forgoing general description and the following detailed description are exemplary, and are intended to provide further explanation of the invention as claimed.

### BRIEF DESCRIPTION OF THE DRAWINGS

The accompanying drawings are included to provide a further understanding of the above-described object, characteristics and advantages of the invention. The drawings illustrate the conventional inducting structure layer and a preferred embodiment of the present invention and, together with the description, serve to explain the principle of the invention. In the drawings,

FIG. 1A is a cross section drawing of a conventional conducting structure layer. The conducting structure layer is located on a substrate;

FIG. 1B is a cross section drawing of a defined conventional conducting structure layer. It shows that residues remain on the dielectric layer;

FIG. 2 is an electron microscope picture showing that, on the conventional conducting structure, there exist residues that can not be completely removed after the etching is conducted.

The drawings from FIG. 3A to FIG. 3E are cross section drawings showing the fabrication process of the conducting structure layer according to the present invention. The conducting structure layer is located on a substrate; and

FIG. 4 is an electron microscope picture showing that, according to the present invention, the point-shaped etching residues on the conducting structure layer can be effectively avoided after the etching.

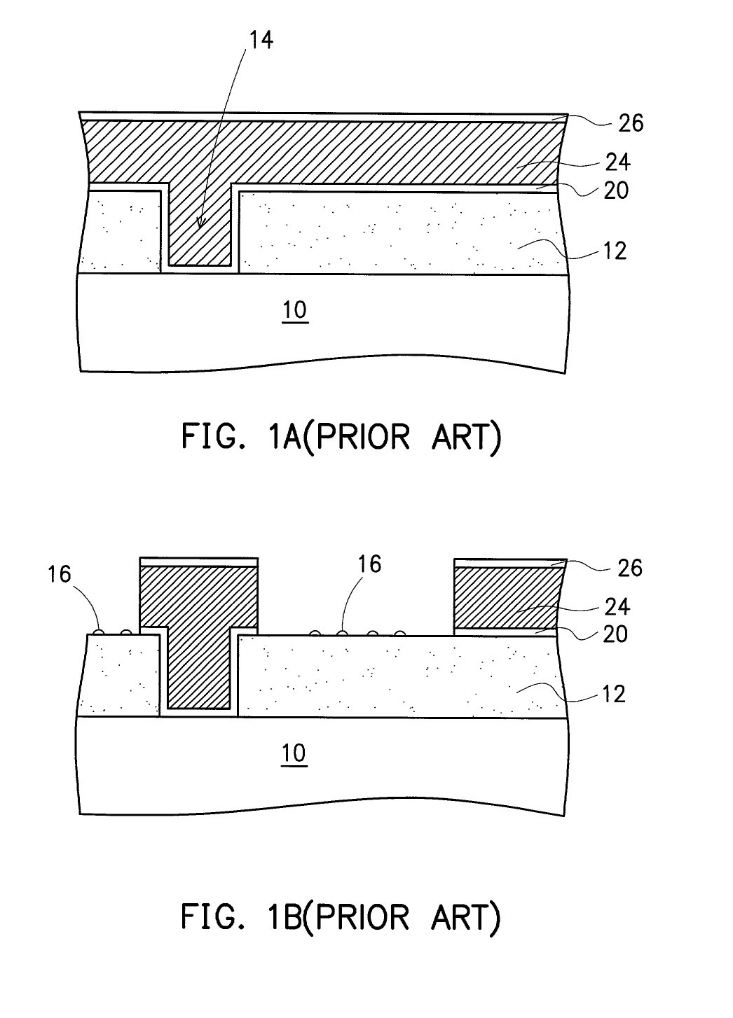

### DESCRIPTION OF THE PREFERRED EMBODIMENT

The present invention provides a process and a structure for forming a conducting structure that can reduce metal etching residues. The characteristics of the invention is that, before a metal layer is deposited, a pre in-situ metal layer is first deposited in the same vacuum device, so that a proper deposit surface is provided for the metal layer. As a result, the growth of the metal layer can be more even and the occurrence of the uneven dopant distribution phenomenon is reduced. In this way the probability of the occurrence of the etching residues is reduced after the etching on the metal layer.

FIG. 3A to FIG. 3D shows a preferred embodiment according to the present invention. They are cross section drawings showing the fabrication process of the conducting structure layer according to the present invention. The conducting structure layer is located on a substrate. The etching residues can be effectively avoided after the etching on the conducting structure layer is conducted. First, please refer to 3A, a dielectric layer 52 is deposited on a semiconductor substrate. Afterwards, an opening 54 is formed on the dielectric layer 52 through a photolithography-etching step. The opening 54 exposes a part of the component area on the substrate 50. (The components are not shown in the drawing.)

Please refer to 3B. Based on the steps shown in 3A, a barrier layer 60 is deposited on the opening 54 and the dielectric layer 52. The barrier layer 60 is conformal to a structure surface on the substrate 50. When the opening 54 is a contact, the barrier layer 60 can comprise, for example, two layers. First a layer of titanium is deposited and then a layer of titanium nitride is deposited. Or, first a layer of titanium is deposited and then a layer of titanium tungsten is deposited. When the opening 54 is a dielectric contact, the barrier layer 60 comprises, for example, either titanium nitride or titanium tungsten. The thickness of the barrier layer 60 is decided by the aspect ratio of the opening. After the barrier layer 60 is deposited, it is processed either by a thermal treatment or by being cooled in the air for a period of time, in order to increase the insulating effect of the barrier layer 60.

Please refer to 3C. Based on the steps shown in 3B, a pre in-situ metal layer 62 is deposited on barrier layer 60. The pre in-situ metal layer can be composed of titanium, or titanium tungsten, or titanium nitride. Titanium nitride is preferable. The thickness of the layer, for example, is about 50 angstroms to about 1 100 angstroms. The pre in-situ metal layer 62 is neither processed with a thermal treatment nor is It cooled in the air for a period of time. It provides a suitable deposition surface. So long as the pre in-situ metal layer is deposited, the function of reducing metal etching residues on conducting structure layer fulfilled.

Please refer to 3D. In the same vacuum device where the pre in-situ metal layer 62 is deposited and under continuous vacuum condition, a metal layer 64 is deposited on the pre in-situ metal layer 62. Generally, an anti-reflective layer 66 may also be deposited on the metal layer 64.

Please refer to 3E. The conducting structure layer that can reduce metal etching residue according the present invention is formed through a photo lithography etching step to define the barrier layer 60, the pre in-situ metal layer 62, the metal layer 64 and the anti-reflective layer 66. Because the metal layer 64 is deposited on the pre in-situ metal layer 62, and the pre in-situ metal layer 62 provides a suitable deposition surface, the crystalloid growth of the metal layer 64 is more even, the occurrences of the uneven dopant distribution phenomenon is reduced, and the probability of etching residues occurred after the conducting structure layer goes through the etching step. The metal layer 64 includes one of the following materials: aluminum, copper, tungsten, an aluminum alloy, an alloy of aluminum and silicon, an alloy of aluminum, silicon and copper, an alloy of aluminum and copper, an copper alloy, or an tungsten alloy. Among these materials, an alloy of aluminum and silicon and an alloy of aluminum, silicon and copper are preferred. The material for the anti-reflective layer 66 is titanium nitride.

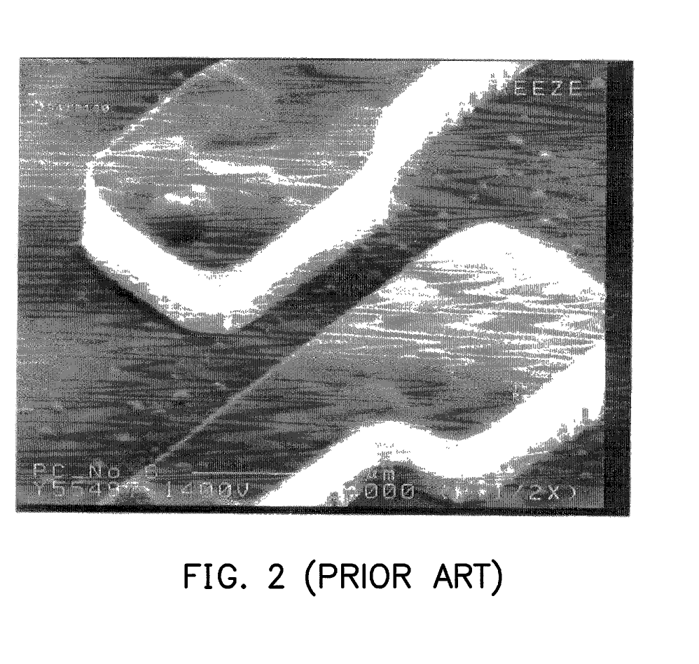

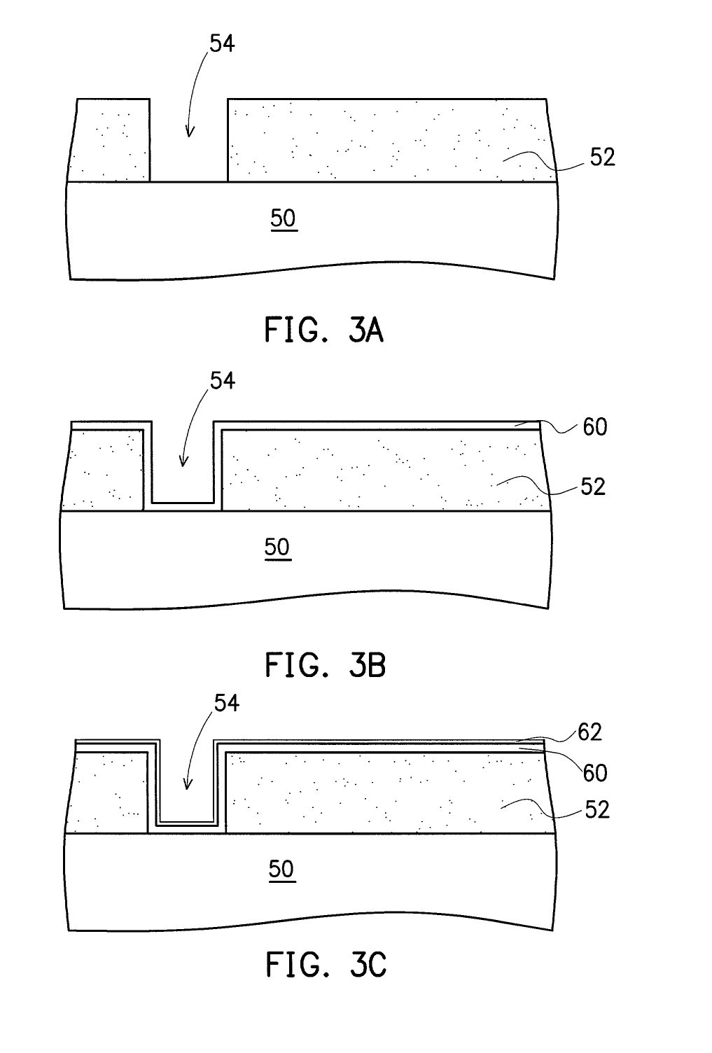

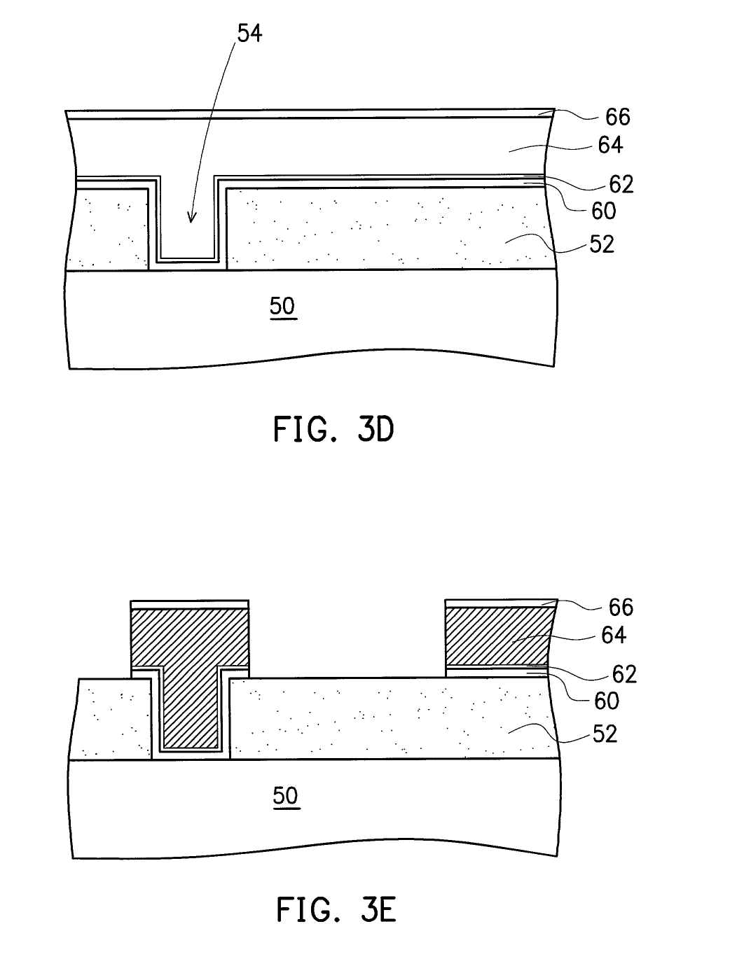

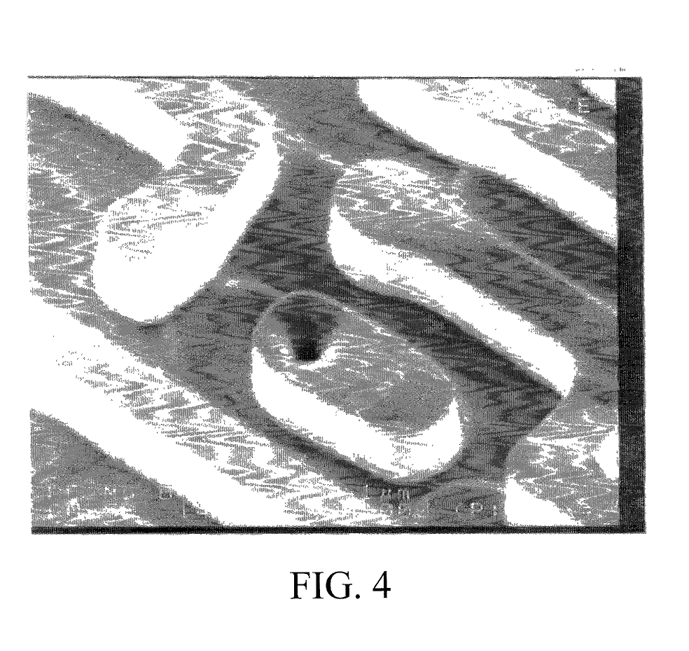

FIG. 4 is an electron microscope picture showing that the point-shaped etching residues have been effectively avoided after the conducting structure layer of the present invention goes through the etching step. Please compare FIG. 4 with FIG. 2. In FIG. 2, point-shaped etching residues spread on the exposed dielectric layer between the conducting structure layer, while in FIG. 4, a pre in-situ metal layer 62 is formed according to method of the present invention before the metal layer 64 is formed. As a result, the conventional point-shaped etching residues can be effectively avoided.

Although the preferred embodiment of the conducting structure layer according to the present invention disclosed in FIG. ˜D includes, for example, a barrier layer 60, a pre in-situ metal layer ˜2, a metal layer 64, and an anti-reflective layer 66, the conducting structure of the invention can actually require only a pre in-situ metal layer 62 and a metal layer 64 to reach the goal of reducing metal etching residues.

To sum up, the method of forming a conducting structure that can reduce metal etching residues according to the invention has many characteristics:

(1) The pre in-situ metal layer in the conducting structure according to the present invention is deposited before the metal layer is deposited. The deposition of both layers belongs to a deposition step in the same vacuum device. Therefore, the degree of difficulty is not increased.

(2) Because the pre in-situ metal layer 62 of the conducting structure layer of the present invention is formed after the etching, the etching residues are effectively avoided.

(3) Because the etching residues are effectively avoided after etching, the conducting structure layer of the present invention can increase the reliability of components.

Although the present invention is disclosed above with a preferred embodiment, it will be apparent to those skilled in the art that various modifications and variations can be made to the present invention without departing from the scope or spirit of the invention. In view of the foregoing, it is intended that the present invention cover modifications and variations of this invention provided they fall within the scope of the following claims and their equivalents.

What is claimed is:

1. A process for forming a conducting structure layer that can reduce metal etching residues, comprising steps as follows:
a substrate is provided;
a barrier layer is formed on the substrate;
a pre in-situ metal layer is formed on the barrier layer; and
a first metal layer is formed immediately after the pre in-situ metal layer is formed and in the same vacuum surrounding as the one in which the pre in-situ metal layer is formed.

2. The method of claim 1, wherein the pre in-situ metal layer includes one of the following materials: titanium, titanium nitride, or titanium tungsten.

3. The method of claim 1, wherein the first metal layer includes one of the following materials: aluminum, copper, tungsten, an alloy of aluminum silicon, an alloy of aluminum, silicon and copper, an alloy of aluminum and copper, an aluminum alloy, an copper alloy, or an tungsten alloy.

4. The method of claim 1, wherein a step for processing the barrier layer is included.

5. The method of claim 4, wherein the step for processing the barrier layer includes either high temperature tempering treatment or cooling in the air for a period of time.

6. The method of claim 4, wherein the barrier layer includes at least a second metal layer.

7. The method of claim 1, wherein the barrier layer includes one of the following materials: titanium, titanium nitride of titanium tungsten.

8. The method of claim 1, wherein the substrate includes a dielectric layer and an opening defined at the dielectric layer.

9. The method of claim 1, a step of depositing an anti-reflective layer on the first metal layer is also included.

10. The method of claim 9, wherein the anti-reflective layer includes titanium nitride in the step of forming the anti-reflective layer.

11. The method of claim 1, a photolithography and a etching step is also included to define the barrier layer, the pre in-situ metal layer, and the first metal layer.

12. A process for forming a conducting structure layer, comprising the following steps:
a substrate is provided;
a pre in-situ metal layer is formed on the substrate; and
a metal layer is formed on the pre in-situ metal layer.

13. The method of claim 12, wherein the metal layer is formed on the pre in-situ metal layer immediately after the pre in-situ metal layer is formed and the metal layer is formed in the same vacuum device in which the pre in-situ metal layer is formed.

14. The method of claim 12, wherein the pre in-situ metal layer includes one of the three materials: titanium, titanium nitride, or titanium tungsten.

15. The method of claim 12, wherein the metal layer includes one of the following materials: aluminum, tungsten, copper, an alloy of aluminum and silicon, an alloy of aluminum, silicon and copper, an alloy of aluminum and copper, an aluminum alloy, an alloy of tungsten, or an alloy of copper.

16. The method of claim 12, a photolithography and etching step is also included to define the pre in-situ metal layer and the metal layer.

17. A structure of conducting structure layer formed on a substrate, comprising: a barrier layer formed on the substrate; a pre in-situ metal layer formed on the barrier layer; and a first metal layer located on the pre in-situ metal layer.

18. The structure of claim 17, wherein the pre in-situ metal layer includes one of the following three materials: titanium, titanium nitride, or titanium tungsten.

19. The structure of claim 17, wherein the first metal layer includes one of the following materials: aluminum, tungsten, copper, an alloy of aluminum and silicon, an alloy of aluminum, silicon and copper, an alloy of aluminum and copper, an aluminum alloy, an alloy of tungsten, or an alloy of copper.

20. The structure of claim 17, wherein the barrier layer includes at least a second metal layer.

21. The structure of claim 17, wherein the barrier layer includes one of the following three materials: titanium, titanium nitride, or titanium tungsten.

22. The structure of claim 17, wherein the substrate includes a dielectric layer and an opening that is defined at the dielectric layer.

23. The structure of claim 17, which also includes an anti-reflective layer. The anti-reflective layer is located on the first metal layer.

24. A structure of conducting structure layer formed on a substrate, comprising:
a pre in-situ metal layer formed on the substrate; and
a metal layer formed on the pre in-situ metal layer.

25. The structure of claim 24, wherein the pre in-situ metal layer includes one of the following three materials: titanium, titanium nitride, or titanium tungsten.

26. The structure of claim 24, wherein the metal layer includes one of the following materials; aluminum, tungsten, copper, an alloy of aluminum and silicon, an alloy of aluminum, silicon and copper, an alloy of aluminum and copper, an aluminum alloy, an alloy of tungsten, or an alloy of copper.
